(19) United States
(12) Patent Application Publication
(10) Pub. No.: US 2024/0426591 A1
(43) Pub. Date: Dec. 26, 2024

(54) DEFORMATION DETECTION SENSOR

(71) Applicant: Murata Manufacturing Co., Ltd., Nagaokakyo-shi (JP)

(72) Inventor: Yoshihito OKUTOMI, Nagaokakyo-shi (JP)

(21) Appl. No.: 18/823,755

(22) Filed: Sep. 4, 2024

Related U.S. Application Data
(63) Continuation of application No. PCT/JP2023/007287, filed on Feb. 28, 2023.

(30) Foreign Application Priority Data
Mar. 14, 2022 (JP) 2022-038838

(51) Int. Cl. G01B 7/16; H10N 30/30

(52) U.S. Cl. CPC G01B 7/16; H10N 30/302

(57) ABSTRACT

A deformation detection sensor includes a bendable flexible substrate having a substrate upper main surface and a substrate lower main surface arranged in a vertical direction, a first sensor provided on the substrate upper main surface and including a first piezoelectric film, and a second sensor provided on the substrate lower main surface and including a second piezoelectric film. Thickness in the vertical direction of the second piezoelectric film is larger than thickness in the vertical direction of the first piezoelectric film, and the first sensor and the second sensor are bent as the flexible substrate is bent so as to project in an upper direction or a lower direction.

### CROSS REFERENCE TO RELATED APPLICATIONS

This application is a continuation of International Application No. PCT/JP2023/007287, filed Feb. 28, 2023, which claims priority to Japanese Patent Application No. 2022-038838, filed Mar. 14, 2022, the contents of each of which are hereby incorporated by reference in their entirety.

### TECHNICAL FIELD

The present disclosure is directed to a deformation detection sensor that detects deformation of a flexible substrate.

### BACKGROUND

An invention related to a conventional deformation detection sensor, for example, a bending deformation sensor is described in Japanese Patent No. 4427665 (hereinafter the “'665 Patent”), incorporated by reference in its entity, is known. The bending deformation sensor includes a first piezoelectric film, a second piezoelectric film, and an elastic body. The elastic body has a first main surface and a second main surface. The first piezoelectric film is provided on the first main surface. The second piezoelectric film is provided on the second main surface. By the above, when the elastic body is bent, the first piezoelectric film stretches and the second piezoelectric film stretches and contracts. Then, the first piezoelectric film outputs a first signal, and the second piezoelectric film outputs a second signal. An arithmetic circuit can detect bending deformation of the elastic body based on the first signal and the second signal.

In the bending deformation sensor described in the '665 Patent, there is a demand for further improving sensitivity of detection of bending deformation.

### SUMMARY OF THE INVENTION

In view of the foregoing, an object of the present disclosures provides a deformation detection sensor that improve sensitivity of detection of deformation of a flexible substrate.

In some aspects, the techniques described herein relate to a deformation detection sensor including: a flexible substrate including a substrate upper main surface and a substrate lower main surface arranged in a vertical direction; a first sensor provided on the substrate upper main surface and including a first piezoelectric film; and a second sensor provided on the substrate lower main surface and including a second piezoelectric film, wherein a thickness in the vertical direction of the second piezoelectric film is larger than a thickness in the vertical direction of the first piezoelectric film, and the first sensor and the second sensor are bent as the flexible substrate is bent so as to project in an upper direction or a lower direction.

In some aspects, the techniques described herein relate to a deformation detection sensor including: a flexible substrate including a substrate upper main surface and a substrate lower main surface arranged in a vertical direction; a first sensor provided on the substrate upper main surface and including a first piezoelectric film; and a second sensor provided on the substrate lower main surface and including a second piezoelectric film, the first sensor and the second sensor are bent as the flexible substrate is bent so as to project in an upper direction or a lower direction wherein the first piezoelectric film has a first upper main surface and a first lower main surface, the second piezoelectric film has a second upper main surface and a second lower main surface.

According to the deformation detection sensor according to the present invention, sensitivity of detection of deformation of a flexible substrate can be improved.

### BRIEF DESCRIPTION OF DRAWINGS

In the descriptions that follow, like parts are marked throughout the specification and drawings with the same numerals, respectively. The drawings are not necessarily drawn to scale and certain drawings may be illustrated in exaggerated or generalized form in the interest of clarity and conciseness. The disclosure itself, however, as well as a mode of use, further features and advances thereof, will be understood by reference to the following detailed description of illustrative implementations of the disclosure when read in conjunction with reference to the accompanying drawings, wherein:

FIG. 1 is a front view of a deformation detection sensor 10 in accordance with aspects of the present disclosure;

FIG. 2 is an exploded view of the deformation detection sensor 10 in accordance with aspects of the present disclosure;

FIG. 3 is a front view of the deformation detection sensor 10 when a flexible substrate 12 is bent in accordance with aspects of the present disclosure;

FIG. 4 is a graph illustrating a waveform of a first signal Sig1 and a second signal Sig2 in accordance with aspects of the present disclosure;

FIG. 5 is a graph illustrating a waveform of a difference A in accordance with aspects of the present disclosure;

FIG. 6 is a front view of a deformation detection sensor 1010 according to a comparative example in accordance with aspects of the present disclosure;

FIG. 7 is a front view of a deformation detection sensor 10a in accordance with aspects of the present disclosure;

FIG. 8 is a front view of the deformation detection sensor 10a when the flexible substrate 12 is bent in accordance with aspects of the present disclosure; and

FIG. 9 is a front view of a deformation detection sensor 10b in accordance with aspects of the present disclosure.

### DETAILED DESCRIPTION OF EMBODIMENTS

Hereinbelow, aspects of the present disclosure will be described. In a following description of the drawings, the same or similar components will be represented with use of the same or similar reference characters. The drawings are exemplary, sizes or shapes of portions are schematic, and technical scope of the present disclosure should not be understood with limitation to the aspects.

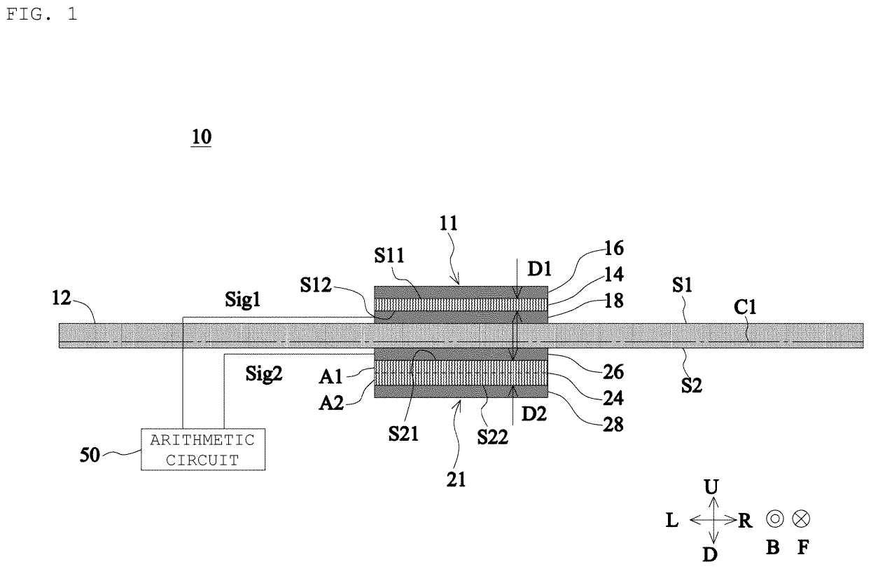

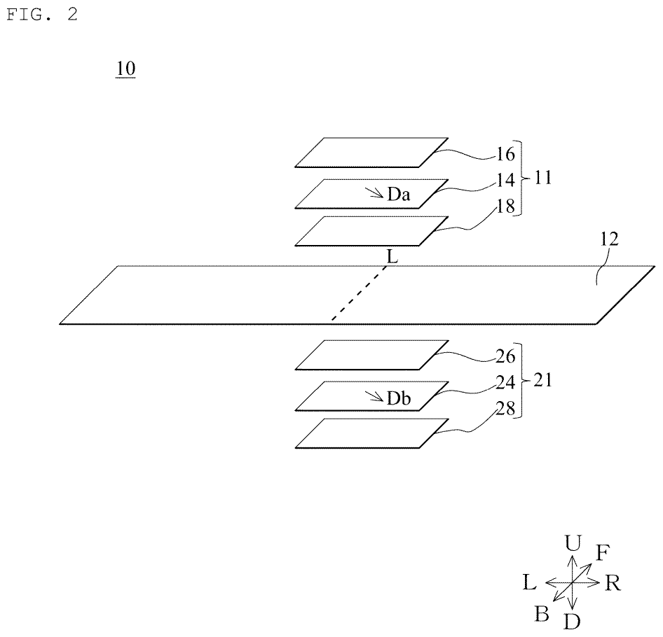

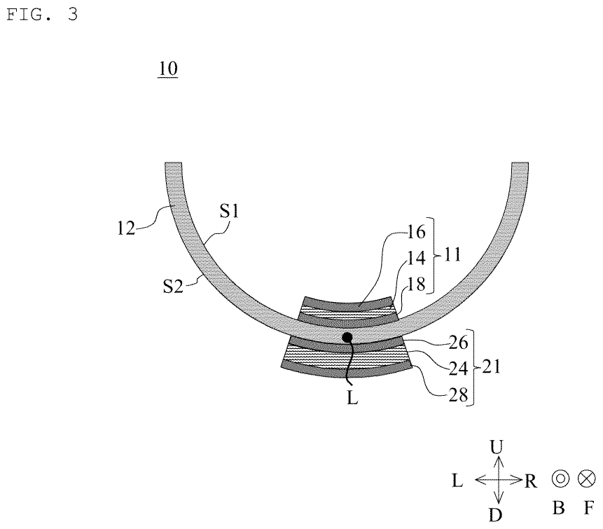

Hereinafter, a structure of a deformation detection sensor 10 according to an aspect of the present disclosure will be described with reference to the drawings. FIG. 1 is a front view of the deformation detection sensor 10. FIG. 2 is an exploded view of the deformation detection sensor 10. FIG. 3 is a front view of the deformation detection sensor 10 when a flexible substrate 12 is bent.

Further, in the present description, a direction is defined as described below. As illustrated in FIG. 1, a direction in which a substrate upper main surface S1 and a substrate lower main surface S2 of the flexible substrate 12 in a non-bent state are arranged is defined as a vertical direction. When the flexible substrate 12 is bent, a direction in which a bending line L (as illustrated in FIGS. 2 and 3) extends is defined as a front-rear direction. A direction orthogonal to the vertical direction and the front-rear direction is defined as a left-right direction. Note that the definition of a direction in the present description is an example. Therefore, a direction at the time of actual use of the deformation detection sensor 10 does not need to coincide with a direction in the present description. Further, the vertical direction may be reversed in FIG. 1. Similarly, the left-right direction may be reversed in FIG. 1. In FIG. 1, the front-rear direction may be reversed.

The deformation detection sensor 10 detects bending of the flexible substrate 12. As illustrated in FIGS. 1 and 2, the deformation detection sensor 10 includes the flexible substrate 12, a first sensor 11, a second sensor 21, and an arithmetic circuit 50.

The flexible substrate 12 is a flexible sheet. The flexible substrate 12 has the substrate upper main surface S1 and the substrate lower main surface S2 arranged in the vertical direction. As illustrated in FIG. 2, the flexible substrate 12 has a rectangular shape having a short side extending in the front-rear direction and a long side extending in the left-right direction when viewed in the vertical direction. As illustrated in FIG. 3, the flexible substrate 12 can be bent at the bending line L. The bending line L connects midpoints of two long sides of the flexible substrate 12. The flexible substrate 12 is bent so as to project downward as viewed in the front-rear direction.

As illustrated in FIG. 1, the first sensor 11 is provided on the substrate upper main surface S1. The first sensor 11 outputs a first signal Sig1 for detecting deformation of the flexible substrate 12. The first sensor 11 includes a first piezoelectric film 14, a first upper electrode 16, and a first lower electrode 18.

The first piezoelectric film 14 is a flexible sheet. The first piezoelectric film 14 has a first upper main surface S11 and a first lower main surface S12. As illustrated in FIG. 2, the first piezoelectric film 14 has a rectangular shape having a short side extending in the front-rear direction and a long side extending in the left-right direction when viewed in the vertical direction.

The first piezoelectric film 14 stretches and contracts together with the flexible substrate 12 to generate a charge. The first piezoelectric film 14 is, for example, a film formed from a chiral polymer. The chiral polymer is, for example, polylactic acid (PLA), particularly poly-L-lactic acid (PLLA). A main chain of PLLA made from a chiral polymer has a helical structure. PLLA has piezoelectricity when it is uniaxially stretched and molecules are oriented. The first piezoelectric film 14 has a piezoelectric constant of d14. Then, uniaxially stretched PLLA generates voltage when the first piezoelectric film 14 is stretched in the left-right direction or compressed in the left-right direction. The first piezoelectric film 14 generates positive voltage when stretched in the left-right direction. The first piezoelectric film 14 generates negative voltage when compressed in the left-right direction. Magnitude of the voltage depends on a differential value of a deformation amount of the first piezoelectric film 14 due to stretching or compression.

As illustrated in FIG. 2, a uniaxial stretching direction Da of the first piezoelectric film 14 forms an angle of 45 degrees with respect to each of the front-rear direction and the left-right direction. This angle of 45 degrees includes, for example, an angle including about 45 degrees±10 degrees. Note that the first piezoelectric film 14 may be a film formed from a ferroelectric substance in which ions are polarized, such as PVDF or PZT subjected to poling processing, instead of PLLA.

The first upper electrode 16 is a ground electrode. Therefore, the first upper electrode 16 is connected to the ground potential. The first upper electrode 16 is provided on the first upper main surface S11. The first upper electrode 16 covers the entire first upper main surface S11. Therefore, a length in the left-right direction of the first piezoelectric film 14 is equal to a length in the left-right direction of the first upper electrode 16. A length in the front-rear direction of the first piezoelectric film 14 is equal to a length in the front-rear direction of the first upper electrode 16.

The first lower electrode 18 is a signal electrode. Therefore, the first signal Sig1 is output from the first lower electrode 18. The first lower electrode 18 is provided on the first lower main surface S12. The first lower electrode 18 covers the entire first lower main surface S12. Therefore, a length in the left-right direction of the first piezoelectric film 14 is equal to a length in the left-right direction of the first lower electrode 18. A length in the front-rear direction of the first piezoelectric film 14 is equal to a length in the front-rear direction of the first lower electrode 18.

The first upper electrode 16 and the first lower electrode 18 are, for example, an organic electrode such as indium tin oxide (ITO) or zinc oxide (ZnO), a metal film by vapor deposition or plating, or a printed electrode film using silver paste.

The second sensor 21 is provided on the substrate lower main surface S2. When viewed in the vertical direction, the second sensor 21 overlaps the first sensor 11. The second sensor 21 outputs the second signal Sig2 for detecting deformation of the flexible substrate 12. The second sensor 21 includes a second piezoelectric film 24, a second upper electrode 26, and a second lower electrode 28.

The second piezoelectric film 24 is a flexible sheet. The second piezoelectric film 24 has a second upper main surface S21 and a second lower main surface S22. The second piezoelectric film 24 has a rectangular shape having a short side extending in the front-rear direction and a long side extending in the left-right direction when viewed in the vertical direction. Thickness D2 in the vertical direction of the second piezoelectric film 24 is larger than thickness D1 in the vertical direction of the first piezoelectric film 14. Thickness in the vertical direction of the piezoelectric film in the present description is, for example, an average value of thickness in the vertical direction of the entire piezoelectric film.

The second piezoelectric film 24 stretches and contracts together with the flexible substrate 12 to generate polarization. The second piezoelectric film 24 is, for example, a film formed from a chiral polymer. The chiral polymer is, for example, polylactic acid (PLA), particularly poly-L-lactic acid (PLLA). A main chain of PLLA made from a chiral polymer has a helical structure. PLLA has piezoelectricity when it is uniaxially stretched and molecules are oriented. The second piezoelectric film 24 has a piezoelectric constant of d14.Then, uniaxially stretched PLLA generates voltage when the second piezoelectric film 24 is stretched in the left-right direction or compressed in the left-right direction. The second piezoelectric film 24 generates positive voltage when stretched in the left-right direction. The second piezoelectric film 24 generates negative voltage when compressed in the left-right direction. Magnitude of the voltage depends on a differential value of a deformation amount of the second piezoelectric film 24 due to stretching or compression.

A uniaxial stretching direction Db of the second piezoelectric film 24 is parallel to the uniaxial stretching direction Da of the first piezoelectric film 14. As illustrated in FIG. 1, the uniaxial stretching direction Db of the second piezoelectric film 24 forms an angle of 45 degrees with respect to each of the front-rear direction and the left-right direction. This angle of 45 degrees includes, for example, an angle including about 45 degrees±10 degrees. Note that the second piezoelectric film 24 may be a film formed from a ferroelectric substance in which ions are polarized, such as PVDF or PZT subjected to poling processing, instead of PLLA.

The second upper electrode 26 is a signal electrode. Therefore, the second signal Sig2 is output from the second upper electrode 26. The second upper electrode 26 is provided on the second upper main surface S21. The second upper electrode 26 covers the entire second upper main surface S21. Therefore, a length in the left-right direction of the second piezoelectric film 24 is equal to a length in the left-right direction of the second upper electrode 26. A length in the front-rear direction of the second piezoelectric film 24 is equal to a length in the front-rear direction of the second upper electrode 26.

The second lower electrode 28 is a ground electrode. Therefore, the second lower electrode 28 is connected to the ground potential. The second lower electrode 28 is provided on the second lower main surface S22. The second lower electrode 28 covers the entire second lower main surface S22. Therefore, a length in the left-right direction of the second piezoelectric film 24 is equal to a length in the left-right direction of the second lower electrode 28. A length in the front-rear direction of the second piezoelectric film 24 is equal to a length in the front-rear direction of the second lower electrode 28.

The second upper electrode 26 and the second lower electrode 28 are, for example, an organic electrode such as indium tin oxide (ITO) or zinc oxide (ZnO), a metal film by vapor deposition or plating, or a printed electrode film using silver paste.

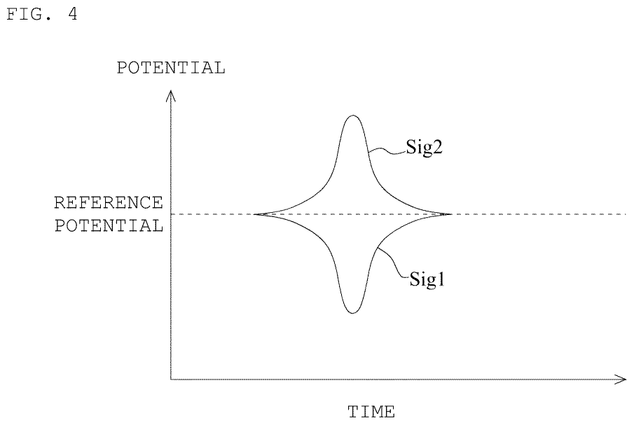

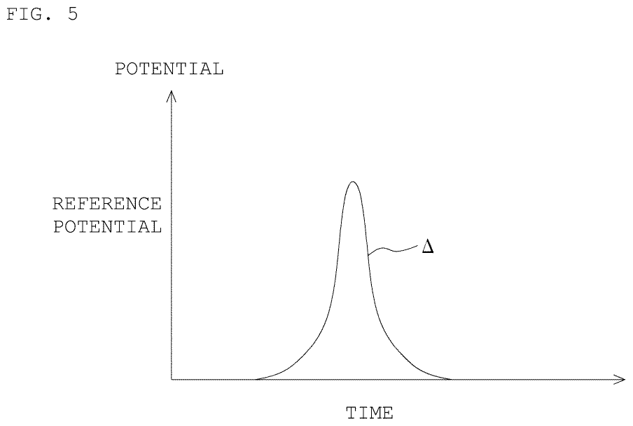

The arithmetic circuit 50 is an integrated circuit (IC). The arithmetic circuit 50 calculates the difference A between an electrical parameter of the first signal Sig1 output from the first lower electrode 18 and an electrical parameter of the second signal Sig2 output from the second upper electrode 26. The electrical parameter is potential. However, the electrical parameter may be a value other than potential. The value other than potential is, for example, a charge amount or a current value. Further, the arithmetic circuit 50 calculates a bending amount of the flexible substrate 12 based on the difference A. Hereinafter, description will be made with reference to the drawings. FIG. 4 is a graph illustrating a waveform of the first signal Sig1 and the second signal Sig2. FIG. 5 is a graph illustrating a waveform of the difference A. The vertical axis in FIGS. 4 and 5 represents potential. The horizontal axis in FIGS. 4 and 5 represents time.

As illustrated in FIG. 3, the flexible substrate 12 is bent so as to project in an upper direction or a lower direction, so that the first sensor 11 and the second sensor 21 are bent. In the present aspect, the flexible substrate 12 is bent so as to project in a lower direction, so that the first sensor 11 and the second sensor 21 are bent. That is, the flexible substrate 12 is bent such that the substrate upper main surface S1 is located inside the substrate lower main surface S2. At this time, the first piezoelectric film 14 is compressed. For this reason, the first signal Sig1 has negative potential with respect to reference potential (hereinafter, simply referred to as negative potential). The second piezoelectric film 24 is stretched. For this reason, the second signal Sig2 has positive potential with respect to reference potential (hereinafter, simply referred to as positive potential). However, a waveform of the first signal Sig1 and a waveform of the second signal Sig2 are line-symmetric with respect to reference potential. In view of the above, the arithmetic circuit 50 subtracts the first signal Sig1 from the second signal Sig2 to calculate the difference A shown in FIG. 5. By the above, the arithmetic circuit 50 can obtain the difference A larger than potential of the first signal Sig1 and potential of the second signal Sig2. Then, the arithmetic circuit 50 calculates a bending amount of the flexible substrate 12 based on the difference A.

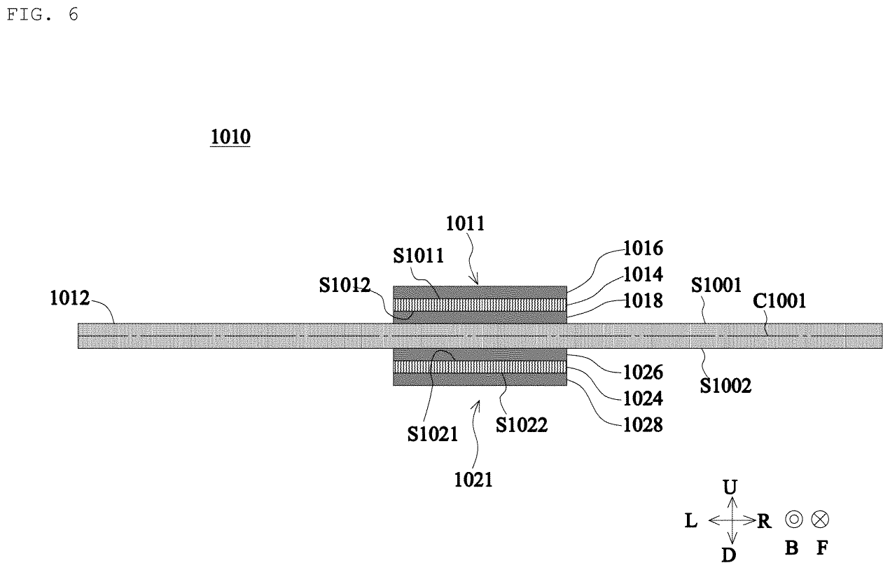

According to the deformation detection sensor 10, sensitivity of detection of deformation of the flexible substrate 12 can be improved. Hereinafter, a deformation detection sensor 1010 according to a comparative example will be described as an example. FIG. 6 is a front view of the deformation detection sensor 1010 according to a comparative example. The deformation detection sensor 1010 according to a comparative example is different from the deformation detection sensor 10 in that thickness in the vertical direction of a second piezoelectric film 1024 is equal to thickness in the vertical direction of a first piezoelectric film 1014.

When the flexible substrates 12 and 1012 are bent, a plane that is not stretched or compressed appears in the flexible substrates 12 and 1012. This plane is referred to as neutral planes C1 and C1001. As illustrated in FIG. 6, the neutral plane C1001 is located between an upper main surface of a first upper electrode 1016 and a second lower electrode 1028. Since thickness in the vertical direction of the second piezoelectric film 1024 is equal to thickness in the vertical direction of the first piezoelectric film 1014, the neutral plane C1001 is located in the middle in the vertical direction of the flexible substrate 1012. In this case, magnitude V1002 of potential generated by stretching of the second piezoelectric film 1024 is substantially equal to magnitude V1001 of potential generated by compression of the first piezoelectric film 1014.

On the other hand, as illustrated in FIG. 1, the neutral plane C1 is located between an upper main surface of the first upper electrode 16 and a lower main surface of the second lower electrode 28. However, since the thickness D2 in the vertical direction of the second piezoelectric film 1024 is larger than thickness D1 of the first piezoelectric film 1014 in the vertical direction, the neutral plane C1 is located below the middle in the vertical direction of the flexible substrate 12. In this case, a compression amount of the first piezoelectric film 14 is larger than a compression amount of the first piezoelectric film 1014. As a result, magnitude V1 of potential generated by compression of the first piezoelectric film 14 is larger than the magnitude V1001 of potential generated by compression of the first piezoelectric film 1014.

Here, a region from the second upper main surface S21 to the thickness D1 in the second piezoelectric film 24 is referred to as a region A1. A region excluding the region A1 in the second piezoelectric film 24 is referred to as a region A2. As described above, the neutral plane C1 is located below the middle in the vertical direction of the flexible substrate 12. In this case, a stretching amount of the region Al is smaller than a stretching amount of the second piezoelectric film 1024. As a result, magnitude VA1 of potential generated by stretching of the region A1 is smaller than the magnitude V1002 of potential generated by stretching of the second piezoelectric film 1024. That is, increase in the magnitude V1 of potential generated by compression of the first piezoelectric film 14 is canceled by decrease in the magnitude VA1 of potential generated by stretching of the region A1.

However, when the flexible substrate 12 is bent, the region A2 stretches. For this reason, the region A2 generates potential of magnitude VA2. Therefore, the deformation detection sensor 10 can obtain the difference A larger by the magnitude VA2 than the difference A obtained by the deformation detection sensor 1010. As a result, according to the deformation detection sensor 10, sensitivity of detection of deformation of the flexible substrate 12 can be improved.

According to the deformation detection sensor 10, sensitivity of detection of deformation of the flexible substrate 12 can be improved also for a reason below. More specifically, the first signal Sig1 has negative potential. The second signal Sig2 has positive potential. However, a waveform of the first signal Sig1 and a waveform of the second signal

Sig2 are line-symmetric with respect to reference potential. In view of the above, the arithmetic circuit 50 subtracts potential of the first signal Sig1 from potential of the second signal Sig2 to calculate the difference A illustrated in FIG. 5. By the above, the arithmetic circuit 50 can obtain the difference A larger than each of potential of the first signal Sig1 and potential of the second signal Sig2. Then, the arithmetic circuit 50 can calculate a deformation amount of the flexible substrate 12 based on the large difference A. As a result, according to the deformation detection sensor 10, sensitivity of detection of deformation of the flexible substrate 12 can be improved.

According to the deformation detection sensor 10, a calculation load of the arithmetic circuit 50 is reduced. More specifically, the arithmetic circuit 50 subtracts potential of the first signal Sig1 from potential of the second signal Sig2 to calculate the difference A illustrated in FIG. 5. At this time, reference potential of the first signal Sig1 is subtracted from reference potential of the second signal Sig2. As a result, at the difference A, reference potential becomes 0 V.

Here, the reference potential is a value that changes from moment to moment. The arithmetic circuit 50 calculating the reference potential one by one in accordance with this fluctuation increases calculation time. In view of the above, there is a method of calculating the reference potential from the first signal Sig1 and the second signal Sig2 acquired in certain time in the past. However, this method has a problem below.

The calculated reference potential is an estimated value for the first signal Sig1 and the second signal Sig2 acquired after the calculation.

Deviation between estimated reference potential and actual reference potential causes deviation in a calculation result of a deformation amount of the flexible substrate 12.

On the other hand, in the deformation detection sensor 10, the reference potential is fixed to 0 V. For this reason, the arithmetic circuit 50 does not need to calculate the reference potential. As a result, a calculation load of the arithmetic circuit 50 is reduced.

According to the deformation detection sensor 10, the second sensor 21 overlaps the first sensor 11 when viewed in the vertical direction. By the above, reduction in size of the deformation detection sensor 10 can be achieved.

In the deformation detection sensor 10, when the flexible substrate 12 is bent, polarity of potential of the first signal Sig1 is different from polarity of potential of the second signal Sig2. For this reason, for example, in a case where polarity of potential of the first signal Sig1 and polarity of potential of the second signal Sig2 are the same, the arithmetic circuit 50 can determine that the deformation detection sensor 10 malfunctions or the flexible substrate 12 undergoes unintended deformation.

In the deformation detection sensor 10, the first upper electrode 16 and the second lower electrode 28 are connected to the ground potential. By the above, the first piezoelectric film 14 is shielded by the first upper electrode 16. The second piezoelectric film 24 is shielded by the second lower electrode 28. As a result, the first sensor 11 and the second sensor 21 are less likely to be affected by noise.

In the deformation detection sensor 10, a length in the left-right direction of the first piezoelectric film 14 is equal to a length in the left-right direction of the first upper electrode 16. By the above, the first piezoelectric film 14 is more reliably shielded by the first upper electrode 16. Similarly, a length in the left-right direction of the second piezoelectric film 24 is equal to a length in the left-right direction of the second lower electrode 28. By the above, the second piezoelectric film 24 is more reliably shielded by the second lower electrode 28. As a result, the first sensor 11 and the second sensor 21 are less likely to be affected by noise.

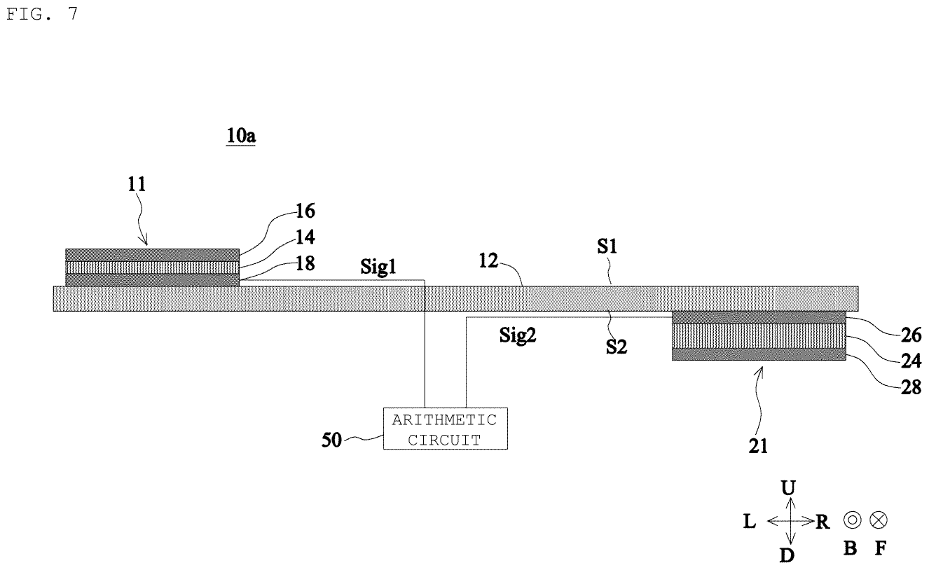

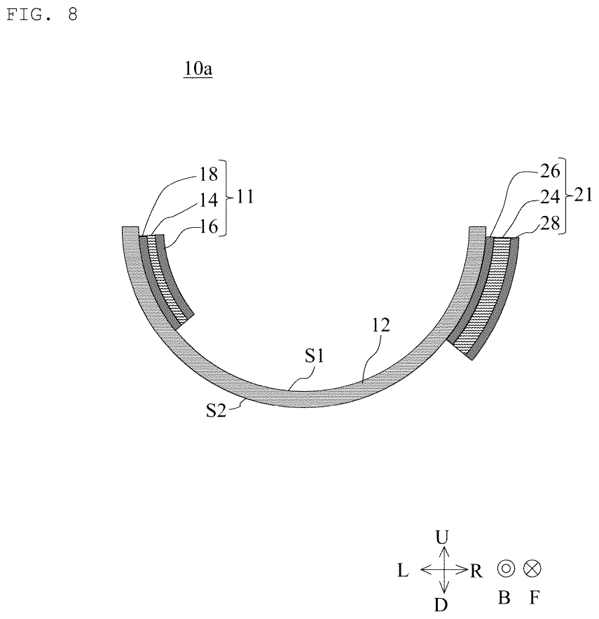

Hereinafter, a deformation detection sensor 10a according to a first variation will be described with reference to the drawings. FIG. 7 is a front view of the deformation detection sensor 10a. FIG. 8 is a front view of the deformation detection sensor 10a when the flexible substrate 12 is bent.

The deformation detection sensor 10a is different from the deformation detection sensor 10 at a position of the first sensor 11 and a position of the second sensor 21. More specifically, the second sensor 21 does not overlap the first sensor 11 when viewed in the vertical direction. However, the first piezoelectric film 14 is compressed when the flexible substrate 12 is bent. The second piezoelectric film 24 is stretched when the flexible substrate 12 is bent. Other structures of the deformation detection sensor 10a are the same as those of the deformation detection sensor 10 and will be omitted from description. The deformation detection sensor 10a can achieve the same action and effect as the deformation detection sensor 10.

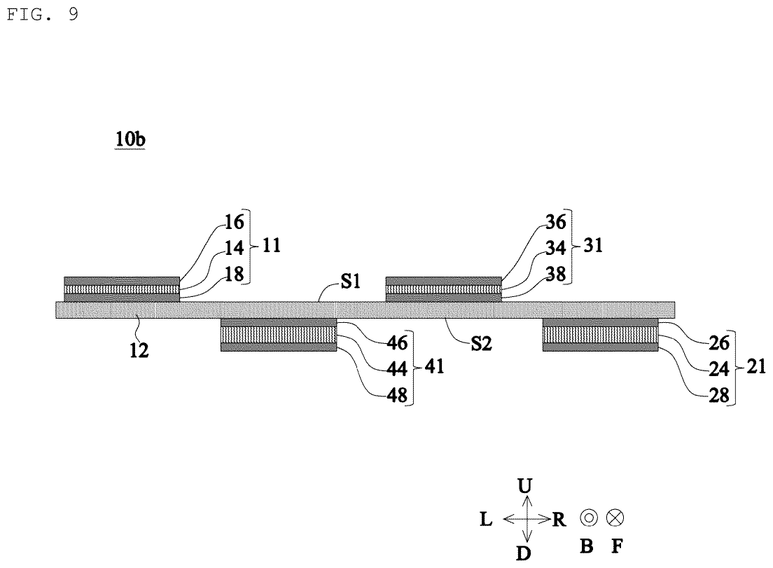

Hereinafter, a deformation detection sensor 10b according to a second variation will be described with reference to the drawings. FIG. 9 is a front view of the deformation detection sensor 10b.

The deformation detection sensor 10v is different from the deformation detection sensor 10a in further including a third sensor 31 and a fourth sensor 41. The third sensor 31 is provided on the substrate upper main surface S1. The third sensor 31 includes a third piezoelectric film 34 that stretches and contracts together with the flexible substrate 12 to generate polarization. However, a structure of the third sensor 31 is the same as that of the first sensor 11, will be omitted from description. The fourth sensor 41 is provided on the substrate lower main surface S2. The fourth sensor 41 includes a fourth piezoelectric film 44 that stretches and contracts together with the flexible substrate 12 to generate polarization. However, a structure of the fourth sensor 41 is the same as that of the second sensor 21 and will be omitted from description. Further, the fourth sensor 41 does not overlap the third sensor 31 when viewed in the vertical direction. Other structures of the deformation detection sensor 10b are the same as those of the deformation detection sensor 10a and will be omitted from description. The deformation detection sensor 10b can achieve the same action and effect as the deformation detection sensor 10a. Further, since the deformation detection sensor 10b includes the third sensor 31 and the fourth sensor 41, a deformation amount can be detected at a plurality of places of the flexible substrate 12.

The deformation detection sensor according to the present disclosure is not limited to the deformation detection sensors 10, 10a, and 10b, and can be modified within the scope of the present disclosure. Further, structures of the deformation detection sensors 10, 10a, and 10b may be optionally combined.

Note that the first piezoelectric film 14, the second piezoelectric film 24, the third piezoelectric film 34, and the fourth piezoelectric film 44 may be a film other than a film formed from a chiral polymer.

Note that the uniaxial stretching direction Db of the second piezoelectric film 24 does not need to be parallel to the uniaxial stretching direction Da of the first piezoelectric film 14. The uniaxial stretching direction Db of the second piezoelectric film 24 may be orthogonal to the uniaxial stretching direction Da of the first piezoelectric film 14. In this case, polarity of potential of the second signal Sig2 is the same as polarity of potential of the first signal Sig1. Therefore, the arithmetic circuit 50 adds potential of the first signal Sig1 and potential of the second signal Sig2.

Note that the first lower electrode 18 and the second upper electrode 26 may be connected to the ground potential.

Note that a length in the left-right direction of the first piezoelectric film 14 does not need to be equal to a length in the left-right direction of the first upper electrode 16. A length in the left-right direction of the second piezoelectric film 24 does not need to be equal to a length in the left-right direction of the second lower electrode 28.

In general, the description of the aspects disclosed should be considered as being illustrative in all respects and not being restrictive. The scope of the present disclosure is shown by the claims rather than by the above description and is intended to include meanings equivalent to the claims and all changes in the scope. While preferred aspects of the invention have been described above, it is to be understood that variations and modifications will be apparent to those skilled in the art without departing from the scope and spirit of the invention.

### Description of Reference Symbols

10, 10a, 10b: Deformation detection sensor
11: First sensor
12: Flexible substrate
14: First piezoelectric film
16: First upper electrode
18: First lower electrode
21: Second sensor
24: Second piezoelectric film
26: Second upper electrode
28: Second lower electrode
31: Third sensor
34: Third piezoelectric film
41: Fourth sensor
44: Fourth piezoelectric film
50: Arithmetic circuit
A1, A2: Region
C1: Neutral plane
L: Bending line
S1: Substrate upper main surface
S11: First upper main surface
S12: First lower main surface
S2: Substrate lower main surface
S21: Second upper main surface
S22: Second lower main surface
Sig1: First signal
Sig2: Second signal

1. A deformation detection sensor comprising:
a flexible substrate including a substrate upper main surface and a substrate lower main surface arranged in a vertical direction;
a first sensor on the substrate upper main surface and including a first piezoelectric film; and
a second sensor on the substrate lower main surface and including a second piezoelectric film,
wherein a thickness in the vertical direction of the second piezoelectric film is larger than a thickness in the vertical direction of the first piezoelectric film, and
wherein the first sensor and the second sensor are bent as the flexible substrate is bent so as to project in an upper direction or a lower direction.

2. The deformation detection sensor according to claim 1, wherein:
the first piezoelectric film includes a first upper main surface and a first lower main surface, and
the second piezoelectric film includes a second upper main surface and a second lower main surface.

3. The deformation detection sensor according to claim 2, wherein:
the first sensor further includes a first upper electrode on the first upper main surface and a first lower electrode on the first lower main surface, and
the second sensor further includes a second upper electrode on the second upper main surface and a second lower electrode on the second lower main surface.

4. The deformation detection sensor according to claim 3, wherein the first upper electrode and the second lower electrode are connected to a ground potential.

5. The deformation detection sensor according to claim 4, further comprising an arithmetic circuit configured to calculate a difference between an electrical parameter of a first signal output from the first lower electrode and an electrical parameter of a second signal output from the second upper electrode.

6. The deformation detection sensor according to claim 4, wherein:
a direction in which a bending line extends when the flexible substrate is bent is defined as a front-rear direction,
a direction orthogonal to the vertical direction and the front-rear direction is defined as a left-right direction,
a length in the left-right direction of the first piezoelectric film is equal to a length in the left-right direction of the first upper electrode, and
a length in the left-right direction of the second piezoelectric film is equal to a length in the left-right direction of the second lower electrode.

7. The deformation detection sensor according to claim 5, wherein:
a direction in which a bending line extends when the flexible substrate is bent is defined as a front-rear direction,
a direction orthogonal to the vertical direction and the front-rear direction is defined as a left-right direction,
a length in the left-right direction of the first piezoelectric film is equal to a length in the left-right direction of the first upper electrode, and
a length in the left-right direction of the second piezoelectric film is equal to a length in the left-right direction of the second lower electrode.

8. The deformation detection sensor according to claim 1, wherein the second sensor overlaps the first sensor when viewed in the vertical direction.

9. The deformation detection sensor according to claim 1, further comprising:
a third sensor on the substrate upper main surface, the third sensor including a third piezoelectric film; and
a fourth sensor on the substrate lower main surface, the fourth sensor including a fourth piezoelectric film.

10. The deformation detection sensor according to claim 1, wherein the first piezoelectric film and the second piezoelectric film have a piezoelectric constant of d14.

11. A deformation detection sensor comprising:
a flexible substrate including a substrate upper main surface and a substrate lower main surface arranged in a vertical direction;
a first sensor on the substrate upper main surface and including a first piezoelectric film; and
a second sensor on the substrate lower main surface and including a second piezoelectric film,
wherein the first sensor and the second sensor are bent as the flexible substrate is bent so as to project in an upper direction or a lower direction,
wherein the first piezoelectric film has a first upper main surface and a first lower main surface, and
the second piezoelectric film has a second upper main surface and a second lower main surface.

12. The deformation detection sensor according to claim 11, wherein:
the first sensor further includes a first upper electrode on the first upper main surface and a first lower electrode on the first lower main surface, and
the second sensor further includes a second upper electrode on the second upper main surface and a second lower electrode on the second lower main surface.

13. The deformation detection sensor according to claim 12, wherein the first upper electrode and the second lower electrode are connected to a ground potential.

14. The deformation detection sensor according to claim 13, further comprising an arithmetic circuit configured to calculate a difference between an electrical parameter of a first signal output from the first lower electrode and an electrical parameter of a second signal output from the second upper electrode.

15. The deformation detection sensor according to claim 13, wherein:
a direction in which a bending line extends when the flexible substrate is bent is defined as a front-rear direction,
a direction orthogonal to the vertical direction and the front-rear direction is defined as a left-right direction,
a length in the left-right direction of the first piezoelectric film is equal to a length in the left-right direction of the first upper electrode, and
a length in the left-right direction of the second piezoelectric film is equal to a length in the left-right direction of the second lower electrode.

16. The deformation detection sensor according to claim 14, wherein:
a direction in which a bending line extends when the flexible substrate is bent is defined as a front-rear direction,
a direction orthogonal to the vertical direction and the front-rear direction is defined as a left-right direction,
a length in the left-right direction of the first piezoelectric film is equal to a length in the left-right direction of the first upper electrode, and
a length in the left-right direction of the second piezoelectric film is equal to a length in the left-right direction of the second lower electrode.

17. The deformation detection sensor according to claim 11, wherein the second sensor overlaps the first sensor when viewed in the vertical direction.

18. The deformation detection sensor according to claim 11, further comprising:
a third sensor on the substrate upper main surface, the third sensor including a third piezoelectric film; and
a fourth sensor on the substrate lower main surface, the fourth sensor including a fourth piezoelectric film.

19. The deformation detection sensor according to claim 11, wherein the first piezoelectric film and the second piezoelectric film have a piezoelectric constant of d14.

20. The deformation detection sensor according to claim 11, wherein a thickness in the vertical direction of the second piezoelectric film is larger than a thickness in the vertical direction of the first piezoelectric film.
